(19) United States
(12) Patent Application Publication
(10) Pub. No.: US 2007/0123059 A1
(43) Pub. Date: May 31, 2007

(54) Methods of internal stress reduction in dielectric films with chemical incorporation and structures formed thereby

(76) Inventors: Michael G. Haverty, Mountain View, CA (US); Grant M. Kloster, Lake Oswego, OR (US); Sadasivan Shankar, Cupertino, CA (US); Boyan Boyanov, Portland, OR (US); Michael D. Goodner, Hillsboro, OR (US); Mansour Moinpour, San Jose, CA (US)

Correspondence Address: INTEL CORPORATION;c/o INTELLEVATE, LLC, P.O. BOX 52050, MINNEAPOLIS, MN, 55402, US

(21) Appl. No.: 11/290,409

(22) Filed: Nov. 29, 2005

(51) Int. Cl. H01L 21/31; H01L 21/469

(52) U.S. Cl. 438/783

(57) ABSTRACT

Methods of forming a microelectronic structure are described. Embodiments of those methods include forming a porous dielectric layer comprising at least one active end group, and bonding at least one large atomic radii species to replace the at least one active end group, wherein a local swelling may be formed within a portion of the porous dielectric.

### BACK GROUND OF THE INVENTION

Microelectronic devices may comprise interconnect structures, such as conductive traces, for example, which may be fabricated in and/or on a dielectric material. To obtain a low dielectric constant, porosity may be introduced into the dielectric material. However, such porosity may affect the mechanical structure of the dielectric material. In some instances, the dielectric material may become weaker or more fragile due to the porosity.

### BRIEF DESCRIPTION OF THE DRAWINGS

While the specification concludes with claims particularly pointing out and distinctly claiming certain embodiments of the present invention, the advantages of this invention can be more readily ascertained from the following description of the invention when read in conjunction with the accompanying drawings in which:

FIGS. 1a-1d represent methods of forming structures according to an embodiment of the present invention.

FIGS. 2a-2b represent methods of forming structures according to the Prior Art.

FIG. 3 represents a flow chart according to an embodiment of the present invention.

FIG. 4 represents a structure according to an embodiment of the present invention.

### DETAILED DESCRIPTION OF THE PRESENT INVENTION

In the following detailed description, reference is made to the accompanying drawings that show, by way of illustration, specific embodiments in which the invention may be practiced. These embodiments are described in sufficient detail to enable those skilled in the art to practice the invention. It is to be understood that the various embodiments of the invention, although different, are not necessarily mutually exclusive. For example, a particular feature, structure, or characteristic described herein, in connection with one embodiment, may be implemented within other embodiments without departing from the spirit and scope of the invention. In addition, it is to be understood that the location or arrangement of individual elements within each disclosed embodiment may be modified without departing from the spirit and scope of the invention. The following detailed description is, therefore, not to be taken in a limiting sense, and the scope of the present invention is defined only by the appended claims, appropriately interpreted, along with the full range of equivalents to which the claims are entitled. In the drawings, like numerals refer to the same or similar functionality throughout the several views.

Methods and associated structures of forming a microelectronic structure, such as a porous dielectric layer, are described. Those methods may comprise forming a porous dielectric layer comprising at least one active end group, and bonding at least one large atomic radii species to replace the at least one active end group, wherein a local swelling may be formed within a portion of the porous dielectric layer.

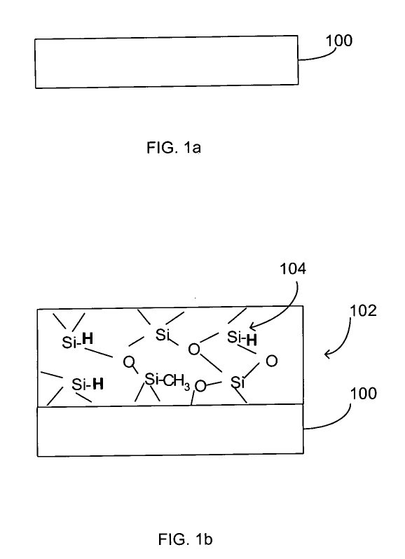

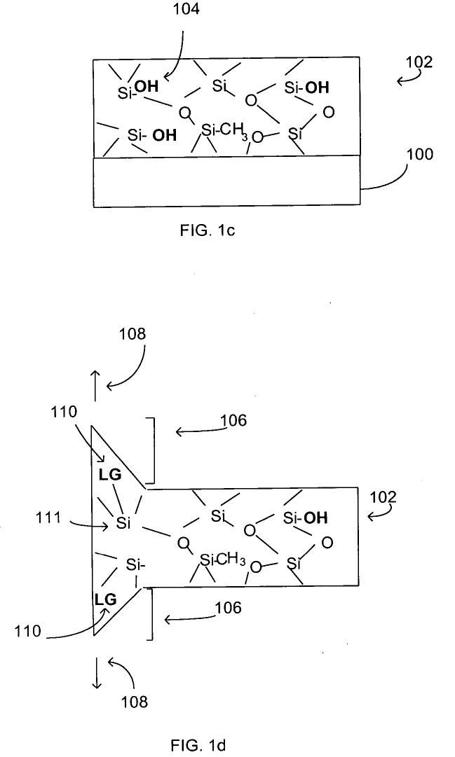

FIGS. 1a-1d illustrate an embodiment of a method of forming a microelectronic structure, such as a porous dielectric structure, for example. FIG. 1a illustrates a substrate 100. The substrate 100 may be comprised of materials such as, but not limited to, silicon, silicon-on-insulator, germanium, indium, antimonide, lead telluride, indium arsenide, indium phosphide, gallium arsenide, gallium antimonide, or combinations thereof. Although several examples of materials from which the substrate 102 may be formed are described here, any material that may serve as a foundation upon which a microelectronic device may be built falls within the spirit and scope of the present invention.

In one embodiment, a porous dielectric layer 102 may be formed on the substrate 100 (FIG. 1b). In one embodiment, the porous dielectric layer 102 may comprise a silicon dioxide material, but may also comprise any other type of dielectric material, depending upon the particular application. In one embodiment, the porous dielectric layer 102 may comprise a low dielectric constant (K), and in some embodiments may comprise a dielectric constant lower than about 3.

In one embodiment, at least one pore or void may be formed within the porous dielectric layer either during a formation process and/or during a subsequent curing process. In one embodiment, the porous dielectric layer 102 may include a porosity. The formation process may include such formation processes as chemical vapor deposition (CVD), and physical vapor deposition processes, by limitation and not limitation, as are well known in the art. In one embodiment, the porous dielectric layer 102 may comprise a thickness between about 100 Angstroms to about 10,000 Angstroms.

In one embodiment, at least one pore-forming agent may be co-deposited with various precursors that may be used to form the porous dielectric layer 102. In one embodiment, the precursors may comprise (by illustration and not limitation) tetraethylorthosilicate (TEOS), tetramethylcyclotetrasiloxane (TMCTS or (TOMCATS), dimenthyldimethoxysilane (DMDMOS), octamethylcyclotetrasiloxane (OMCTS), tetramethoxysilane (TMOS), and diacetoxyditertiarybutoxysilane (DADBS). In one embodiment, the at least one pore forming agent may comprise PLC (hyperbranched poly(caprolactone)) with hydroxyl end groups, PEO-b-PPO-PEO (triblock copolymer, poly(ethylene oxide-b-propylene oxide-b-ethylene oxide), copolymers of PEO (poly(ethylene oxide)) and copolymers of PPO ((poly(propylene oxide)), by illustration and not limitation.

In one embodiment, the at least one pore-forming agent may comprise sacrificial nanoparticles or “porogens” that may be desorbed and/or decomposed during a subsequent process, such as during a curing process, for example. Such desorbing may leave pores, voids, and/or air gaps within the porous dielectric layer 102. In one embodiment, the porous dielectric layer 102 may comprise a porosity between about 20 to about 80 percent. In one embodiment, porosity that may be present within the porous dielectric layer 102 may weaken the mechanical structure of the porous dielectric layer 102, since structural supports within the porous dielectric layer 102 film may be removed as pores are generated, for example.

Additionally, the porous dielectric layer 102, may comprise at least one active end group 104, also known as “dangling groups” or “dangling bonds”. For example in one embodiment, when the porous dielectric layer 102 comprises silicon dioxide, the at least one active end group 104 may comprise Si—H and Si—OH, by illustration and not limitation. In other embodiments, the at least one active end group 104 that may be bonded to silicon may comprise H, Si, -OH, and/or any type of molecular end group that may tend to react among each other and cause cross-linking (as is known in the art) between proximate silicon atoms among the active end groups. Such cross-linking may lead to film shrinkage, which may result in some embodiments in an increased internal tensile stress of the porous dielectric layer 102.

In some embodiments, an increase in the internal tensile stress of the porous dielectric layer 102 may cause the porous dielectric layer 102 to exhibit a lowered mechanical strength. In some cases, a porous dielectric layer with lowered mechanical strength may be more prone to cracking and/or breaking when subjected to subsequent processing, such as during chemical mechanical polishing and packaging processes, for example.

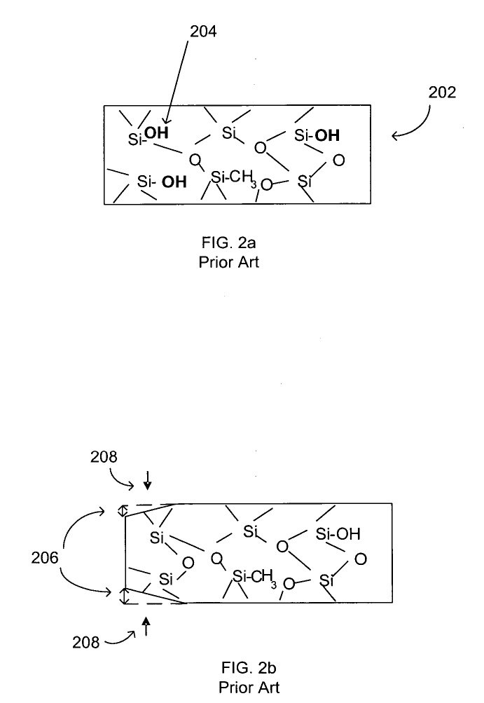

In one embodiment, the at least one active end group 104 of the porous dielectric layer 102 may become hydrolyzed to form Si—OH, for example, due to exposure to moisture that may be present in an ambient environment (FIG. 1c). In some situations, the porous dielectric layer 102 may be susceptible to localized shrinking, as described previously. For example, FIG. 2a depicts a prior art porous dielectric layer 202 wherein at least one active end group 204 (Si—OH in this example) may cross-link among one another and may cause localized shrinking 206 (FIG. 2b) and/or a decrease in molar volume within the porous dielectric layer 202. The localized shrinking 206 may create an internal tensile stress 208 that may cause mechanical weakness within such a film.

Referring back to FIG. 1d, in one embodiment of the present invention, the porous dielectric layer 102 may be treated with at least one large atomic radii species 110 (depicted as LG in FIG. 1d). In one embodiment, the at least one large atomic radii species 110 may function to block the at least one active end group 104 from cross-linking to one another. In one embodiment, the at least one large atomic radii species 110 may be bonded within the porous dielectric layer 102 (by replacing the at least one active end group 104), and thus may block cross-linking within the porous dielectric layer 102. In one embodiment, the at least one large atomic radii species 110 may be bonded to a dangling atom 111 of the porous dielectric layer 102.

The dangling atom 111 may comprise the atom previously bonded to the at least one active end group 104 that has been replaced. For example, in the case of the Si—OH bond, the at least one large atomic radii species 110 may bond to the silicon atom by replacing the hydroxyl group. In one embodiment, the at least one large atomic radii species 110 may comprise a species comprising an atomic and/or molecular radii larger than the atomic and/or molecular radii of hydrogen. In one embodiment, the at least one large atomic radii species 110 may comprise any large atomic and/or molecular radii species that may be bonded to other groups, such as in the case of methyl groups, for example LG(CH₃)₃.

In one embodiment, the incorporation and/or bonding of the at least one large atomic radii species 110 may induce a region of localized swelling 106 and/or increase in molar volume within the porous dielectric layer 102. In one embodiment, the molar volume of the porous dielectric layer 102 may be increased by a range of about 20 percent to about 80 percent.

The localized swelling 106 may create an internal compressive stress 108 that may serve to counteract any internal tensile stress that may be caused by cross linking effects that may occur within the porous dielectric layer 102. The internal localized swelling 106 may thus effect an increase in the mechanical strength of the porous dielectric layer 102 by decreasing the overall tensile stress within the porous dielectric layer 102. In one embodiment, the overall stress of the porous dielectric layer 102 comprising the at least one large atomic radii species replacing the at least one active end group may be less than about 57 MPa.

In one embodiment, the at least one large atomic radii species 110 may comprise a halogen species, such as chlorine, fluorine, bromine and iodine. Halogens comprise in general large atomic radii of about 71 to about 133 picometers, and in general comprise a relatively lower mobility within a dielectric film than other species such as hydrogen and oxygen. Utilization of relatively low mobility species may result in less device degradation when such a porous dielectric film incorporating large atomic radii bonded to replace active end groups, as in certain embodiments of the present invention, is used in a microelectronic device.

In some embodiments, the at least one large atomic radii species 110 may comprise any species that may replace the at least one active end group 104 (i.e., may bond to the silicon atom of the porous dielectric layer 102) and that may induce a local swelling 106 within the porous dielectric layer 102. In one embodiment, the local swelling 106 may form a region of compressive stress 108 within the porous dielectric layer that is substantially near a bonding region between the at least one large atomic radii species 110 and the atoms (for example, the silicon atoms) that are bonded to the at least one large atomic radii species 110. In one embodiment, the at least one large atomic radii species 110 may bond with the porous dielectric layer 102 while not substantially increasing the dielectric constant of the porous dielectric layer 102, which in some embodiments may comprise a dielectric constant below about 3.

In one embodiment, the at least one large atomic radii species 110 may be incorporated within the porous dielectric layer 102 and/or bonded to the porous dielectric layer 102 during the formation of the porous dielectric layer 102. In another embodiment, the at least one large atomic radii species 110 may be incorporated and/or bonded to the porous dielectric layer 102 after the formation of the porous dielectric layer 102.

In some embodiments, a curing step may be subsequently performed on the porous dielectric layer 102. In one embodiment, the at least one large atomic radii species 110 may be introduced and/or bonded within the porous dielectric layer 102 either before, during or after such a curing process. The process parameters, such as temperature and time of the curing step, may vary depending upon the particular application and materials. It will be understood that the timing of the incorporation of the at least one large atomic radii species 110 will depend upon the particular application, i.e., the incorporation may be performed during the formation of the porous dielectric layer 102, and/or before, during and after the curing step, including combinations of those processes thereof.

In one embodiment, the incorporation of the at least one large atomic radii species 110 may comprise introduction before, during and/or after a curing process that may comprise at least one of electron beam curing, ultraviolet curing, evaporation, or thermal curing, as are well known in the art. Such curing may serve to allow the pore-forming agent to decompose to generate pores within the porous dielectric layer 102. Additionally, in one embodiment, the porous dielectric layer 102 may be capped after incorporation of the large atomic radii species 110. Such capping may comprise passivating the porous dielectric layer 102 with a pore sealing layer. In one embodiment, the pore sealing layer may be less than about 20 angstroms thick (thus minimizing its contribution to the dielectric constant value of the porous dielectric layer 102) and may including species selected from the group consisting of siloxane films, amorphous carbon, or polymers, for example.

In one embodiment, the large atomic radii species 110 may be incorporated by utilizing an insertion reaction of the type Si—H+XY→SiX+HY (where X is a halogen, and Y may be a halogen or other species), for example. In another embodiment, the incorporation may be enabled by flowing a halide gas over the porous dielectric layer 102 at elevated temperatures, before, during or after the curing process. In general, bonding large atomic radii species to replace the active end groups of the porous dielectric layer 102 (through any incorporation method appropriate to the particular application) may induce local swelling of the molecular networks near pore walls. This swelling may exert an opposing stress to any pore collapsing reactions that may, which will enable a lower overall internal film stress of the porous dielectric layer 102.

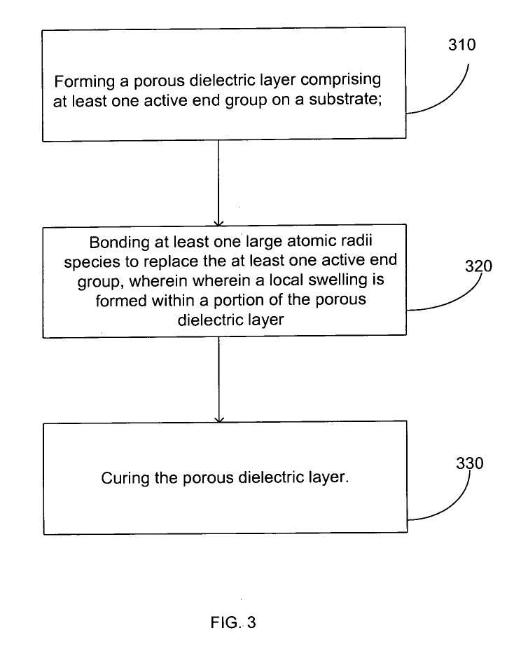

FIG. 3 depicts a flow chart illustrating a method according to an embodiment of the present invention. The method includes forming a porous dielectric layer comprising at least one active end group on a substrate 310, bonding at least one large atomic radii species to replace the at least one active end group, wherein a local swelling is formed within a portion of the porous dielectric layer 320, and curing the porous dielectric layer 330. In other embodiments, the at least one large atomic radii species may be bonded to the at least one active end group before, during and/or after the curing process.

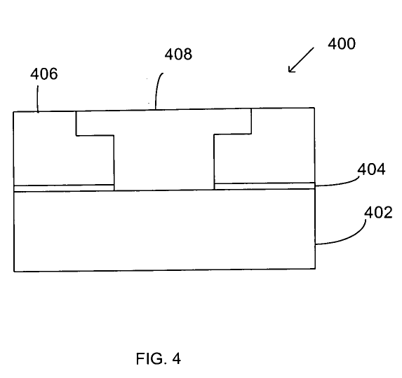

FIG. 4 depicts a microelectronic device 400 that may utilize a porous dielectric layer that may be formed according to the methods of the present invention. A substrate 402 is provided, which may comprise several active devices (e.g., transistor or capacitor) as are well know in the art. The substrate 402 may be a portion of a semiconductor die (and for example, may comprise silicon, monocrystalline silicon, or polycrystalline silicon).

The substrate 402 may also comprise other structures such as gates, local interconnects, metal layers, or other active/passive device structures or layers (not shown). In one embodiment, an etch stop layer 404 may be disposed on the substrate 402 which can be comprised of numerous materials, such as a dielectric material for example. The etch stop layer 404 may be used in a dual-damascene process, as is well known in the art, to form interconnects for the microelectronic device 400. In one embodiment, the etch stop layer 404 may comprise silicon nitride or silicon carbide.

The microelectronic device 400 may further comprise a porous dielectric layer 406, that may be formed according to embodiments of the present invention. The porous dielectric layer 406 may be disposed on the substrate 402 and on the etch stop layer 404. The porous dielectric layer 406 may be porous, and may comprise a low dielectric constant K (e.g., less than about 3, for example, or in some embodiments less than about 2.7 or, in some embodiments, less than about 2.5).

The porous dielectric layer 406 may comprise active end groups (e.g., Si—H or Si—OH) that may be replaced by large atomic radii species (not shown) according to embodiments of the present invention, so that cross-linking among the active end groups is substantially minimized or mitigated, and localized swelling creates compressive stress that may counteract tensile that may be present within the porous dielectric layer 406. In one embodiment, the porous dielectric layer 406 may be formed to have a porosity of about 25% to about 80%. In one embodiment, the size of the pores within the porous dielectric layer 406 may range from about 10 to about 30 Angstroms. In one embodiment, the porous dielectric layer 406 may comprise a thickness in the range of 100-10000 Angstroms.

The microelectronic device 400 may further comprise interconnects such as interconnect 408. In one embodiment, the interconnect 408 may comprise a metal conductor which may comprise copper, for example. In other embodiments, the metal conductor may include a copper alloy or some other conductive metal.

Although the foregoing description has specified certain steps and materials that may be used in the method of the present invention, those skilled in the art will appreciate that many modifications and substitutions may be made. Accordingly, it is intended that all such modifications, alterations, substitutions and additions be considered to fall within the spirit and scope of the invention as defined by the appended claims. In addition, it is appreciated that various microelectronic structures are well known in the art. Therefore, the Figures provided herein illustrate only portions of an exemplary microelectronic structure that pertains to the practice of the present invention. Thus the present invention is not limited to the structures described herein.

What is claimed is:

1. A method comprising:
forming a porous dielectric layer comprising at least one active end group on a substrate; and
bonding the at least one large atomic radii species to the porous dielectric layer to replace the at least one active end group, wherein a local swelling is formed within a portion of the porous dielectric layer.

2. The method of claim 1 further comprising curing the porous dielectric layer.

3. The method of claim 2 wherein curing the porous dielectric layer comprises bonding additional large atomic radii species to replace additional at least one active end groups before, during or after the curing.

4. The method of claim 1 wherein forming the porous dielectric layer comprises:
co-depositing precursors for the porous dielectric layer and pore-forming agents in the porous dielectric layer; and
decomposing the pore-forming agents for form pores in the porous dielectric layer.

5. The method claim 1 wherein forming the porous dielectric layer comprises forming the porous dielectric layer wherein the porous dielectric layer comprises a porosity in a range of about 25% to 80%.

6. The method of claim 1 wherein the local swelling is formed further comprises forming a region of compressive stress within the porous dielectric layer that is substantially near a bonding region between the at least one large atomic radii species and the replaced at least one active end group.

7. The method of claim 1 wherein the at least one active end group is selected from the group consisting of H, Si, OH, Si—H and Si—OH.

8. The method of claim 1 wherein the at least one large atomic radii species comprises halogens.

9. The method of claim 1 wherein the forming the porous dielectric layer comprises forming the porous dielectric layer wherein the porous dielectric layer comprises a stress of less than about 57 MPa.

10. The method of claim 1 wherein forming the porous dielectric layer comprises forming the porous dielectric layer wherein the porous dielectric layer comprises a dielectric constant below about 3.0.

11. The method of claim 1 wherein forming the porous dielectric layer further comprises co-depositing precursors comprising LG(CH₃)₃.

12. A method comprising:
forming a porous dielectric layer comprising at least one active group;
curing the porous dielectric layer; and
bonding at least one large atomic radii species to replace the at least one active end group, wherein a local swelling is formed within a portion of the porous dielectric layer.

13. The method of claim 12 wherein forming a porous dielectric layer further comprises co-depositing large atomic radii species precursors comprising LG(CH₃)₃.

14. The method of claim 12 wherein curing the porous dielectric layer further comprises flowing a halide gas over the porous dielectric layer prior to, during, or after curing.

15. The method of claim 12 wherein the at least one active end group is selected from the group consisting of H, Si, OH, Si—H and Si—OH.

16. The method of claim 12 wherein the at least one large atomic radii species comprises halogens.

17. A structure comprising:
a porous dielectric layer comprising at least one large atomic radii species bonded to a dangling atom of the porous dielectric layer; and
a region of local swelling within a portion of the porous dielectric layer.

18. The structure of claim 17 wherein the region of local swelling comprises a region of compressive stress within the porous dielectric layer that is substantially near a bonding region between the at least one large atomic radii species and the dangling atom of the porous dielectric layer.

19. The structure of claim 17 wherein the porous dielectric layer has a porosity in a range of about 25% to about 80%.

20. The structure of claim 17 wherein the dangling atom comprises a silicon atom.

21. The structure of claim 17 wherein the at least one large atomic radii species comprises halogens.

22. The structure of claim 17 wherein the porous dielectric layer is between about 100 angstroms and about 10,000 angstroms in thickness.

23. The structure of claim 17 wherein the porous dielectric layer comprises a stress of less than about 57 MPa.

24. The structure of claim 17 wherein the porous dielectric layer comprises a dielectric constant below about 3.
